(19) United States
(12) Patent Application Publication
(10) Pub. No.: US 2025/0257181 A1
(43) Pub. Date: Aug. 14, 2025

(54) PREPREG, LAMINATED PLATE, PRINTED WIRING BOARD, AND SEMICONDUCTOR PACKAGE

(71) Applicant: Resonac Corporation, Tokyo (JP)

(72) Inventors: Yuzuru KOBAYASHI, Tokyo (JP); Tomohiko KOTAKE, Tokyo (JP)

(21) Appl. No.: 18/859,112

(22) PCT Filed: Jul. 26, 2023
(86) PCT No.: PCT/JP2023/027415

§ 371 Date: Oct. 22, 2024

(30) Foreign Application Priority Data
Jul. 28, 2022 (JP) 2022-120826

(51) Int. Cl. C08J 5/24; B32B 15/08; C08K 3/013; H01L 23/14; H05K 1/03

(52) U.S. Cl. CPC C08J 5/249; C08J 5/244; C08K 3/013; B32B 15/08; B32B 2457/08; C08J 2379/08; H01L 23/145; H05K 1/0366; H05K 2201/0209

(57) ABSTRACT

Provided is a prepreg which can exhibit dimensional stability of a substrate (laminated plate). In addition, provided are a laminated plate, a printed wiring board, and a semiconductor package, each obtained using the prepreg. Specifically, provided are a prepreg including: a thermosetting resin composition containing a thermosetting resin (A) and an inorganic filler (B), or a semicured product thereof; and one fiber substrate, in which the prepreg has a high filled region having an inorganic filler (B) content of 45% by volume or more, and a low filled region having an inorganic filler (B) content of less than 45% by volume, and the like.

### TECHNICAL FIELD

The present disclosure relates to a prepreg, a laminated plate, a printed wiring board, and a semiconductor package.

### BACKGROUND ART

In mobile communication devices, such as a mobile phone, apparatuses for the communication base stations, network infrastructure devices, such as a server and a router, and various types of electronic devices, such as a large-sized computer, signals used for the devices are being further increased in the speed and capacity. Meanwhile, in recent years, there is an increasing strong demand for electronic devices having improved performance and reduced size, and, as silicon chips are scaled down, narrow pitch connection is making progress. For meeting the demand for such high density mounting, in order to stably mount electronic parts on a substrate, it is further important to suppress a dimensional change of the substrate caused upon mounting. As a method for improving the dimensional stability and the like, the use of a thermosetting resin composition containing a specific siloxane compound and maleimide compound as a substrate material has been known (see, for example, PTL 1).

### CITATION LIST

### Patent Literature

PTL 1: JP 2018-131590 A

### SUMMARY OF INVENTION

### Technical Problem

However, the method described in PTL 1 has a problem in that the resin component of the substrate material is limited in order to improve the dimensional stability and the like. Therefore, the development of another method that can improve the dimensional stability of the substrate without restricting the substrate material is desired.

Accordingly, an object of the present disclosure is to provide a prepreg which can exhibit dimensional stability of a substrate (laminated plate), and to provide a laminated plate, a printed wiring board, and a semiconductor package, each obtained using the prepreg.

### Solution to Problem

The present inventors have conducted extensive and intensive studies. As a result, it has been found that the resin composition in the present disclosure can achieve the above-mentioned object.

The present disclosure includes embodiments of the following items [1] to [9].
[1] A prepreg including:
a thermosetting resin composition containing a thermosetting resin (A) and an inorganic filler (B), or a semicured product thereof; and
one fiber substrate,
in which the prepreg has a high filled region having an inorganic filler (B) content of 45% by volume or more, and a low filled region having an inorganic filler (B) content of less than 45% by volume.
[2] The prepreg according to item [1] above, in which the high filled region has an inorganic filler (B) content of 55% by volume or more.
[3] The prepreg according to item [1] or [2] above, in which the high filled region and the low filled region are in a layer form.
[4] The prepreg according to item [3] above, which has two layers or more of the high filled region.
[5] The prepreg according to any of items [1] to [4] above, in which the thermosetting resin (A) contains at least one member selected from the group consisting of an epoxy resin, a maleimide compound, a phenolic resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.
[6] The prepreg according to any of items [1] to [5] above, in which the inorganic filler (B) contains at least one member selected from the group consisting of silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, a molybdic acid compound, talc, aluminum borate, and silicon carbide.
[7] A laminated plate including: a cured product of the prepreg according to any of items [1] to [6] above; and a metal foil.
[8] A printed wiring board including a cured product of the prepreg according to any of items [1] to [6] above.
[9] A semiconductor package including: the printed wiring board according to item [8] above; and a semiconductor element.

### Advantageous Effects of Invention

By the present disclosure, there can be provided a prepreg which can exhibit dimensional stability of a substrate (laminated plate), and there can be provided a laminated plate, a printed wiring board, and a semiconductor package, each obtained using the prepreg.

### BRIEF DESCRIPTION OF DRAWINGS

FIG. 1 is a diagrammatic cross-sectional view showing one mode of the prepreg of the present embodiment.

FIG. 2 is a diagrammatic cross-sectional view showing one mode of the prepreg of the present embodiment.

FIG. 3 is a diagrammatic cross-sectional view showing one mode of the prepreg of the present embodiment.

FIG. 4 is a diagrammatic cross-sectional view showing one mode of the prepreg of the present embodiment.

FIG. 5 is a diagrammatic cross-sectional view showing a mode of the prepreg prepared in Comparative Example 1.

### DESCRIPTION OF EMBODIMENTS

In a numerical value range described in the present description, the upper limit value and the lower limit value of the numerical value range can be substituted by each value described in the Examples. In addition, the lower limit value and the upper limit value in the numerical value range are each arbitrarily combined with the lower limit value or the upper limit value of another numerical value range. In the expression “numerical value range AA to BB”, the numerical values AA and BB that are both ends are contained in the numerical value range as the lower limit value and the upper limit value, respectively.

In the present description, for example, the expression “10 or more” means 10 and a numerical value exceeding 10, and, in the case of different numerical values, this is also adopted. For example, the expression “10 or less” means 10 and a numerical value less than 10, and, in the case of different numerical values, this is also adopted.

With respect to the components and materials described in the present description, the components or the materials can be used individually or in combination unless otherwise specified. In the present description, when a plurality of types of substances corresponding to each of the components are present in the composition, the content of each of the components in the composition means the total content of the substances present in the composition unless otherwise specified.

In the present description, the term “resin components” means all the solids constituting the resin composition, except inorganic compounds, such as the below-mentioned inorganic filler.

In the present description, the term “solids” means the components, exclusive of the below-mentioned organic solvent, and the component which is in a liquid state at 25° C. is regarded as solids.

In the present description, the expression “containing (or contain(s)) XX” means both containing XX which is in such a state that XX has been reacted and containing merely XX.

An embodiment having an arbitrary combination of the matters described in the present description is included in the present disclosure and the present embodiment.

### [Prepreg]

The prepreg of the present embodiment is a prepreg having a thermosetting resin composition containing a thermosetting resin (A) and an inorganic filler (B) or a semicured product thereof, and one fiber substrate,
in which the prepreg has a high filled region having an inorganic filler (B) content of 45% by volume or more [hereinafter, frequently referred to simply as “high filled region”], and a low filled region having an inorganic filler (B) content of less than 45% by volume [hereinafter, frequently referred to simply as “low filled region”].

The prepreg having one fiber substrate has the high filled region and the low filled region, and therefore can exhibit high dimensional stability of a substrate (laminated plate). The reason that such a result can be obtained is presumed that, by virtue of forming the high filled region, the high filled region prevents a heat shrinkage action which is likely to be caused in the low filled region. Further, the prepreg having one fiber substrate has the high filled region and the low filled region, and therefore the transmission loss is likely to be reduced. Particularly, the prepreg has not only the high filled region but also the low filled region, and therefore it is likely that an increase of the specific permittivity (Dk) can be suppressed.

From the viewpoint of the dimensional stability, in the high filled region, the inorganic filler (B) content is preferably 50% by volume or more, more preferably 55% by volume or more.

Similarly, from the viewpoint of the dimensional stability, it is preferred that, in the high filled region, the inorganic filler (B) content is 45 to 95% by volume and that, in the low filled region, the inorganic filler (B) content is 10 to less than 45% by volume, it is preferred that, in the high filled region, the inorganic filler (B) content is 50 to 80% by volume and that, in the low filled region, the inorganic filler (B) content is 10 to 40% by volume, it is more preferred that, in the high filled region, the inorganic filler (B) content is 55 to 70% by volume and that, in the low filled region, the inorganic filler (B) content is 15 to 40% by volume, and it is further preferred that, in the high filled region, the inorganic filler (B) content is 55 to 70% by volume and that, in the low filled region, the inorganic filler (B) content is 20 to 35% by volume.

From the viewpoint of the dimensional stability, it is preferred that the high filled region and the low filled region are in a layer form. When the high filled region and the low filled region are in a layer form, it is likely that the high filled region easily prevents a heat shrinkage action caused in the low filled region. When the high filled region and the low filled region are in a layer form, the high filled region and the low filled region can be referred to as “high filled layer” and “low filled layer”, respectively. From the viewpoint of the dimensional stability, the prepreg of the present embodiment preferably has two layers or more of the high filled region, more preferably 2 to 6 layers, further preferably 2 to 4 layers, especially preferably 2 layers of the high filled region.

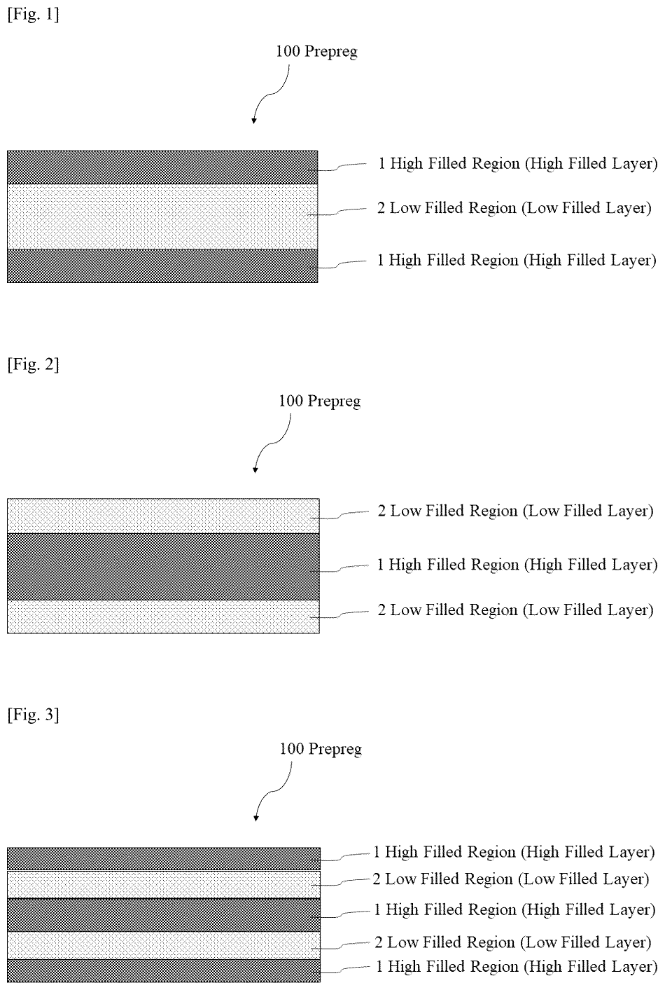

Preferred modes of the prepreg of the present embodiment are shown in FIGS. 1 to 4. All of the modes shown in the figures are a prepreg having a thermosetting resin composition containing a thermosetting resin (A) and an inorganic filler (B) or a semicured product thereof, and one fiber substrate, but the fiber substrate is not shown.

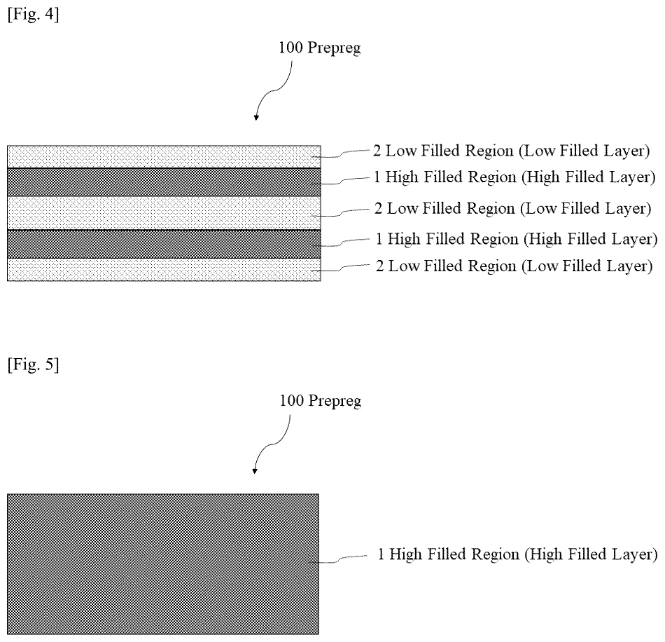

FIG. 1 shows a prepreg having a low filled region (low filled layer) 2 disposed between high filled regions (high filled layers) 1. FIG. 2 shows a prepreg having a high filled region (high filled layer) 1 disposed between low filled regions (low filled layers) 2. FIG. 3 shows a prepreg having a layer form of high filled region (high filled layer) 1-low filled region (low filled layer) 2-high filled region (high filled layer) 1-low filled region (low filled layer) 2-high filled region (high filled layer) 1 in this order. FIG. 4 shows a prepreg having a layer form of low filled region (low filled layer) 2-high filled region (high filled layer) 1-low filled region (low filled layer) 2-high filled region (high filled layer) 1-low filled region (low filled layer) 2 in this order.

The prepregs shown in FIGS. 1 to 4, which have plane symmetry as viewed in the vertical direction, are preferred from the viewpoint of improving the easy handling of the prepreg because the prepreg itself is unlikely to suffer warpage.

From the viewpoint of the dimensional stability, any of the prepregs shown in FIGS. 1 to 4 is preferred, and particularly, the prepreg shown in FIG. 1 or the prepreg shown in FIG. 3 is preferred. From the viewpoint of the easy production, the prepreg shown in FIG. 1 or the prepreg shown in FIG. 2 is more preferred. Further, preferred is the prepreg having the low filled region 2 near the center inside of the prepreg as shown in, e.g., FIGS. 1 and 4, because it is likely that the fiber substrate can be easily impregnated with the thermosetting resin composition, making it possible to suppress formation of voids. Further, preferred is the prepreg having the low filled region 2 in the outermost layer as shown in, e.g., FIGS. 2 and 4, because the bond strength to a conductor is likely to be increased.

In the prepreg of the present embodiment, with respect to the thickness of the high filled region (high filled layer) 1, there is no particular limitation, but the thickness of the high filled region 1 is preferably 5 to 35 μm, more preferably 10 to 30 μm, further preferably 15 to 25 μm. When the thickness of the high filled region (high filled layer) 1 is 5 μm or more, it is likely that the dimensional stability is excellent, and, when the thickness of the high filled region 1 is 35 μm or less, it is likely that the prepreg of the present embodiment can have satisfactory room to contain the low filled region (low filled layer) 2.

In the prepreg of the present embodiment, with respect to the thickness of the low filled region (low filled layer) 2, there is no particular limitation, but the thickness of the low filled region 2 is preferably 5 to 35 μm, more preferably 10 to 30 μm, further preferably 15 to 25 μm. When the thickness of the low filled region (low filled layer) 2 is 5 μm or more, it is likely that the specific permittivity (Dk) can be reduced, and particularly, when the low filled region (low filled layer) 2 is positioned near the center of the prepreg, it is likely that the fiber substrate can be easily impregnated with the thermosetting resin composition, making it possible to suppress formation of voids. When the thickness of the low filled region 2 is 35 μm or less, it is likely that the prepreg of the present embodiment can have increased room to contain the high filled region (high filled layer) 1.

With respect to the thickness of the prepreg of the present embodiment, there is no particular limitation, but the thickness of the prepreg can be 20 to 200 μm, can be 30 to 150 μm, or can be 40 to 120 μm.

### (Method for Producing the Prepreg)

With respect to the method for producing the prepreg of the present embodiment, there is no particular limitation. For example, there are first individually prepared: a resin film which is formed from a thermosetting resin composition containing a thermosetting resin (A) and an inorganic filler (B), and which is used for the high filled region having an inorganic filler (B) content of 45% by volume or more; and a resin film which is formed from a thermosetting resin composition containing a thermosetting resin (A) and an inorganic filler (B), and which is used for the low filled region having an inorganic filler (B) content of less than 45% by volume.

The resin film can be produced by, for example, applying the thermosetting resin composition containing the below-mentioned organic solvent to a support, and drying the applied composition by heating and, if necessary, causing the composition to be semicured (B-staged). In the present description, the term “B-staged” means the B-staged state defined in JIS K6900 (1994).

Examples of supports include a plastic film, a metal foil, and release paper.

The drying temperature and drying time when preparing the resin film can be appropriately selected according to the amount of the organic solvent used and the boiling point of the organic solvent used or the like, but the resin film can be advantageously formed by drying at 50 to 200° C. for about 1 to 10 minutes.

A fiber substrate is impregnated with the resin films while laminating the desired number of resin films in the desired order, preparing the prepreg of the present embodiment. With respect to the method for laminating the desired number of resin films in the desired order, there is no particular limitation, but the resin films can be merely laminated on one another, or can be laminated at 60 to 140° C. using a roll laminator or the like. Further, with respect to the method for impregnating the fiber substrate with the resin film, there is no particular limitation, and a known method, such as a method in which impregnation is made using a roll laminator at 80 to 200° C., can be employed.

With respect to the fiber substrate, there is used one which is known and used in a laminated plate for various electrically insulating materials. Examples of materials for the fiber substrate include inorganic fibers, such as E glass, D glass, S glass, and Q glass; organic fibers, such as polyimide, polyester, and tetrafluoroethylene; and a mixture thereof. The fiber substrate has a form of, for example, woven fabric, nonwoven fabric, roving, chopped strand mat, or surfacing mat.

The fiber substrate is preferably a sheet-form fiber substrate.

With respect to the thickness of the fiber substrate, there is no particular limitation, but the thickness of the fiber substrate can be 1 to 100 μm, can be 3 to 70 μm, can be 5 to 55 μm, can be 15 to 55 μm, or can be 25 to 55 μm.

The components contained in the thermosetting resin composition or semicured product thereof, which the prepreg of the present embodiment contains, are described below.

### [Resin Composition]

The thermosetting resin composition or semicured product thereof, which the prepreg of the present embodiment contains, contains a thermosetting resin (A) [hereinafter, frequently referred to as “component (A)”] and an inorganic filler (B) [hereinafter, frequently referred to as “component (B)”].

### ((A) Thermosetting Resin)

Examples of the component (A) include an epoxy resin, a maleimide compound, a phenolic resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. Of these, the component (A) preferably contains at least one member selected from the group consisting of an epoxy resin, a maleimide compound, a phenolic resin, a polyimide resin, a cyanate resin, and an isocyanate resin, more preferably at least one member selected from the group consisting of an epoxy resin and a maleimide compound, further preferably a maleimide compound from the viewpoint of the low thermal expansion and the like. With respect to the maleimide compound, there is no particular limitation, but, from the viewpoint of reduction of the specific permittivity (Dk) and dielectric loss tangent (Df), the maleimide compound is preferably of a form containing an indan ring-containing aromatic bismaleimide. The indan ring-containing aromatic bismaleimide is commercially available.

With respect to the component (A), the thermosetting resins can be used individually or in combination.

### (Amount of the Component (A))

With respect to the amount of the thermosetting resin (A) contained in the thermosetting resin composition, there is no particular limitation, but, from the viewpoint of the heat resistance and moldability, the amount of the thermosetting resin (A), relative to 100 parts by mass of the total of the resin components in the resin composition, is preferably 5 to 95 parts by mass, more preferably 10 to 80 parts by mass, further preferably 10 to 70 parts by mass, especially preferably 15 to 60 parts by mass, most preferably 15 to 45 parts by mass.

### ((B) Inorganic Filler)

With respect to the component (B), there is no particular limitation, but examples include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay (such as calcined clay), a molybdic acid compound, such as zinc molybdate, talc, aluminum borate, and silicon carbide. With respect to the component (B), the inorganic fillers can be used individually or in combination. Of these, from the viewpoint of the coefficient of thermal expansion, heat resistance, and flame retardancy, silica, alumina, mica, or talc is preferred, silica or alumina is more preferred, and silica is further preferred. Examples of silica include crushed silica, fumed silica, and fused silica (fused spherical silica).

With respect to the shape and particle diameter of the component (B), there is no particular limitation, but the particle diameter of the component (B) is preferably 0.01 to 20 μm, more preferably 0.1 to 10 μm, further preferably 0.2 to 5 μm, especially preferably 0.3 to 3 μm, and can be 0.3 to 1.5 μm, or can be 0.3 to 1.0 μm. The particle diameter indicates an average particle diameter which is a particle diameter at a point corresponding to 50% volume in a cumulative frequency distribution curve of particle diameter as determined when taking the total volume of the particles as 100%. The particle diameter of the component (B) can be measured by means of a particle size distribution measurement apparatus or the like using a laser diffraction/scattering method.

### (Content of the Component (B))

The content of the component (B) in the thermosetting resin composition is the same as the content of the component (B) in the prepreg. Specifically, the content of the component (B) in the thermosetting resin composition for the high filled region can be 45 to 95% by volume, can be 55 to 80% by volume, or can be 55 to 70% by volume. Further, the content of the component (B) in the thermosetting resin composition for the low filled region can be 10 to less than 45% by volume, can be 10 to 40% by volume, can be 15 to 40% by volume, or can be 20 to 35% by volume.

Further, for the purpose of improving the dispersibility of the component (B) and the adhesion of the component (B) to the organic components in the thermosetting resin composition, if necessary, a coupling agent can be used in combination with the component (B). With respect to the coupling agent, there is no particular limitation, and, for example, a silane coupling agent or a titanate coupling agent can be appropriately selected and used. The coupling agents can be used individually or in combination. Further, with respect to the amount of the coupling agent used, there is no particular limitation.

When a coupling agent is used, a so-called integral blend treatment method can be employed in which the component (B) is incorporated into the thermosetting resin composition and then a coupling agent is added, but preferred is a method using an inorganic filler obtained by preliminarily subjecting an inorganic filler to surface treatment with a coupling agent by a dry process or a wet process. By employing this method, the component (B) can exhibit the characteristic features thereof more effectively.

### (Additional Component)

The thermosetting resin composition can further contain, as an additional component, at least one member selected from the group consisting of a thermoplastic resin, a compatibilizer, a flame retardant, a flame retardant auxiliary, a curing accelerator, an antioxidant, an adhesion improving agent, a heat stabilizer, an antistatic agent, an ultraviolet light absorber, a pigment, a coloring agent, and a lubricant. Further, the thermosetting resin composition can contain a component other than those mentioned above.

### (Organic Solvent)

The thermosetting resin composition in the present embodiment can be used in the form of a so-called “varnish” containing an organic solvent from the viewpoint of easy handling of the composition and from the viewpoint of facilitating the below-mentioned production of the prepreg or resin film.

With respect to the organic solvent, there is no particular limitation, but examples of organic solvents include alcohol solvents, such as ethanol, propanol, butanol, methyl Cellosolve, butyl Cellosolve, and propylene glycol monomethyl ether; ketone solvents, such as acetone, methyl ethyl ketone, methyl isobutyl ketone, and cyclohexanone; ether solvents, such as tetrahydrofuran; aromatic solvents, such as toluene, xylene, and mesitylene; nitrogen atom-containing solvents, such as dimethylformamide, dimethylacetamide, and N-methylpyrrolidone; sulfur atom-containing solvents, such as dimethyl sulfoxide; and ester solvents, such as γ-butyrolactone. From the viewpoint of the solubility, ketone solvents are preferred, and methyl ethyl ketone is more preferred. The organic solvents can be used individually or in combination.

When the thermosetting resin composition is used in the form of a varnish, the solids content of the varnish is preferably 30 to 90% by mass, more preferably 40 to 80% by mass, further preferably 45 to 60% by mass. When the solids content of the resin composition is in the above range, handling of the thermosetting resin composition is easy, and the application properties of the composition are excellent when forming a resin film from the composition.

The thermosetting resin composition can be produced by mixing together the component (A) and the component (B) as well as the optionally usable component mentioned above by a known method. In this instance, the components can be dissolved or dispersed in the above-mentioned organic solvent while stirring. With respect to the conditions for mixing, such as the order of mixing and temperature and time for mixing, there is no particular limitation, and the conditions can be arbitrarily selected.

### [Laminated Plate]

The laminated plate of the present embodiment is a laminated plate having a cured product of the prepreg of the present embodiment, and a metal foil.

The laminated plate of the present embodiment can be produced by, for example, disposing a metal foil on one surface or both surfaces of the one prepreg of the present embodiment, or disposing a metal foil on one surface or both surfaces of a laminated material obtained by laminating the two or more prepregs of the present embodiment (preferably 2 to 30 prepregs, more preferably 2 to 20 prepregs, further preferably 4 to 15 prepregs), and then subjecting the resultant material to heat pressure molding. In the laminated plate obtained by the above-mentioned method, the prepreg of the present embodiment is C-staged. In the present description, the term “C-staged” means the C-staged state defined in JIS K6900 (1994). The laminated plate having a metal foil is also referred to as “metal-clad laminated plate”.

With respect to the metal for the metal foil, there is no particular limitation, but, from the viewpoint of the electrical conductivity, the metal can be copper, gold, silver, nickel, platinum, molybdenum, ruthenium, aluminum, tungsten, iron, titanium, chromium, or an alloy containing the above one or more metal elements, and copper or aluminum is preferred, and copper is more preferred.

With respect to the method of conducting the heat pressure molding, there is no particular limitation, but the heat pressure molding can be conducted, for example, under conditions such that the temperature is 100 to 300° C., the pressure is 0.2 to 10 MPa, and the time is 0.1 to 5 hours. Further, in the heat pressure molding, a method can be employed in which the vacuum state is maintained for 0.5 to 5 hours using a vacuum press or the like.

### [Printed Wiring Board]

The printed wiring board of the present embodiment has a cured product of the prepreg of the present embodiment.

The printed wiring board of the present embodiment can be produced using the laminated plate of the present embodiment by conducting perforation processing, metal plating processing, and circuit forming processing by etching a metal foil or the like by a known method. Further, if necessary, a multilayer printed wiring board can be produced by further conducting multilayer bonding processing. In the printed wiring board of the present embodiment, the prepreg of the present embodiment is C-staged.

### [Semiconductor Package]

The semiconductor package of the present embodiment is a semiconductor package having the printed wiring board of the present embodiment and a semiconductor element. The semiconductor package of the present embodiment can be produced by mounting a semiconductor element, such as a semiconductor chip or a memory, on the printed wiring board of the present embodiment at a predetermined position, and subjecting the semiconductor element to encapsulation using an encapsulation resin or the like.

The prepreg, laminated plate, printed wiring board, and semiconductor package of the present embodiment can be advantageously used in an electronic device which handles high frequency signals at 10 GHz or more. Particularly, the printed wiring board is advantageously used as a printed wiring board for millimeter-wave radar.

Hereinabove, the preferred embodiments were described, but these embodiments are examples for explaining the present disclosure, and should not be construed as limiting the scope of the present disclosure. The present disclosure includes various modes different from the above-descried embodiments as long as the effects of the present disclosure can be obtained.

### EXAMPLES

Hereinbelow, the present embodiment will be described in more detail with reference to the following Examples, which should not be construed as limiting the scope of the present embodiment.

In the following Examples, a number average molecular weight (Mn) was measured by the method described below.

### (Measurement Method for Number Average Molecular Weight)

A number average molecular weight was determined from a conversion calibration curve obtained using standard polystyrene by gel permeation chromatography (GPC). The calibration curve was approximated by a cubic equation using standard polystyrene: TSK standard POLYSTYRENE (Type: A-2500, A-5000, F-1, F-2, F-4, F-10, F-20, F-40) [trade name, manufactured by Tosoh Corp.]. Conditions for the GPC measurement are shown below.

### [Conditions for GPC Measurement]

Apparatus: High speed GPC apparatus HLC-8320GPC
Detector: Ultraviolet absorption detector UV-8320 [manufactured by Tosoh Corp.]
Columns: guard column; TSK Guard column SuperHZ-L+ column; TSKgel SuperHZM-N+ TSKgel SuperHZM-M+ TSKgel SuperH-RC (trade names, each of which is manufactured by Tosoh Corp.)
Column size: 4.6×20 mm (guard column), 4.6×150 mm (column), 6.0×150 mm (reference column)
Eluent: Tetrahydrofuran
Sample concentration: 10 mg/5 mL
Sample amount per injection: 25 μL
Flow rate: 1.00 mL/minute
Temperature for measurement: 40° C.

### [Production Example 1] Preparation of Modified Conjugated Diene Polymer 1

Into a glass flask vessel having a volume of 2 L, which is equipped with a thermometer, a reflux condenser, and a stirrer and capable of heating and cooling the contents, were charged the raw materials shown in Table 1 and toluene as an organic solvent. Then, the resultant mixture was subjected to reaction while stirring in a nitrogen gas atmosphere at 90 to 100° C. for 5 hours, obtaining a solution of modified conjugated diene polymer 1 (solids content: 35% by mass).

TABLE 1

| | | Production Example |
|---|---|---|
| | Unit | 1 |
| Type of modified conjugated | — | 1 |
| diene polymer | | |
| Polybutadiene | Parts by mass | 33.8 |
| Bismaleimide compound | Parts by mass | 1.43 |
| Organic peroxide | Parts by mass | 0.035 |
| Number average molecular weight | — | 1,700 |
| of modified conjugated diene | | |
| polymer | | |

When used in the form of a solution or a dispersion, the amount of the component shown in the table is in terms of the amount of the solids.

Details of the raw materials shown in Table 1 are as follows.
Polybutadiene: 1,2-Polybutadiene homopolymer; number average molecular weight=1,200; vinyl group content=85% or more
Bismaleimide compound: Indan ring-containing aromatic bismaleimide compound (number average molecular weight=1,300)
Organic peroxide: reaction catalyst; α,α′-Bis(t-butylperoxy)diisopropylbenzne

### Production Examples 2 to 4

### (Preparation of a Varnish)

In accordance with the formulation shown in Table 2, the components shown in Table 2 and toluene were stirred and mixed while heating at 25° C. or 50 to 80° C., preparing a thermosetting resin composition (varnish) A having an inorganic filler content of 30% by volume, a thermosetting resin composition (varnish) B having an inorganic filler content of 45% by volume, or a thermosetting resin composition (varnish) C having an inorganic filler content of 60% by volume. (Preparation of a resin film)

The above-obtained varnishes were individually applied to a polyethylene terephthalate (PET) film having a thickness of 50 μm, and then B-staged by drying and heating at 110° C. for 5 minutes, preparing PET film-having resin films A to C (each of which had a thickness of 20 μm).

TABLE 2

| | | | Production Example | | |
|---|---|---|---|---|---|
| | | Unit | 2 | 3 | 4 |
| Type of thermosetting resin composition, | | — | A | B | C |
| and type of resin film | | | | | |
| Component (A) | Maleimide | Parts by | 27 | 27 | 27 |
| | compound 1 | mass | | | |
| Component (B) | Inorganic filler 1 | phr^{*1} | 90 | 180 | 330 |
| | | (% by | (30) | (45) | (60) |
| | | volume) | | | |
| Thermoplastic | Thermoplastic | Parts by | 32 | 32 | 32 |
| resin | elastomer 1 | mass | | | |
| Compatibilizer | Modified conjugated | Parts by | 32 | 32 | 32 |
| | diene polymer 1 | mass | | | |
| Flame retardant | Flame retardant 1 | Parts by | 8 | 8 | 8 |
| | | mass | | | |
| Curing accelerator | Organic peroxide 1 | Part by | 1 | 1 | 1 |
| | | mass | | | |

When used in the form of a solution or a dispersion, the amount of the component shown in the table is in terms of the amount of the solids.
^{*1}: Amount (parts by mass), relative to 100 parts by mass of the total of the resin components

Details of the components shown in Table 2 are as follows.

### [(A) Thermosetting Resin]

Maleimide compound 1: Indan ring-containing aromatic bismaleimide; number average molecular weight=1,300

### [(B) Inorganic Filler]

Inorganic filler 1: Spherical silica; average particle diameter=0.5 μm

### [Thermoplastic Resin]

Thermoplastic elastomer 1: “Tuftec (registered trademark) H1221” (manufactured by Asahi Kasei Corporation), hydrogenated styrene thermoplastic elastomer (SEBS); styrene unit content=12% by mass; number average molecular weight=170,000

### [Compatibilizer]

Modified conjugated diene polymer 1: Modified conjugated diene polymer 1 prepared in Production Example 1

### [Flame Retardant]

Flame retardant 1: Aluminum trisdiethylphosphinate

### [Curing Accelerator]

Organic peroxide 1: α,α′-Bis(t-butylperoxy)diisopropylbenzne

### Example 1

### (Preparation of a Prepreg)

The PET film-having resin film A and the PET film-having resin film C were disposed so that the resin films were in contact with each other, obtaining a laminated material having a construction of “PET film-resin film A-resin film C-PET film”. Then, while heating at 100° C., the resin film C was laminated onto the resin film A using a roll laminator. Then, the PET film on the resin film A side was peeled off, preparing a laminated resin film. The same procedure was repeated, so that the same two laminated resin films were obtained.

The obtained laminated resin films were individually disposed on both sides of an E glass cloth having a thickness of 40 μm so that the resin film A faced the glass woven fabric, and subjected to lamination using a roll laminator while heating at 150° C., and then the PET films on both sides were peeled off, preparing a prepreg having the construction of FIG. 1.

### (Preparation of a Double-Sided Copper-Clad Laminated Plate)

The thus obtained six prepregs were laminated on one another to obtain a laminated material, and electrolytic copper foils having a thickness of 12 μm were disposed on both sides of the laminated material so that the M surface (matte surface) was in contact with the prepreg, and then subjected to heat pressure molding under conditions at a temperature of 230° C. under a pressure of 4 MPa for 120 minutes, preparing a double-sided copper-clad laminated plate 1.

Using the obtained double-sided copper-clad laminated plate 1, a dimensional change rate was measured in accordance with the method described below. The results are shown in Table 3.

### Example 2

### (Preparation of a Prepreg)

The PET film-having resin film A and the PET film-having resin film C were disposed so that the resin films were in contact with each other, obtaining a laminated material having a construction of “PET film-resin film A-resin film C-PET film”. Then, while heating at 100° C., the resin film C was laminated onto the resin film A using a roll laminator. Then, the PET film on the resin film C side was peeled off, preparing a laminated resin film. The same procedure was repeated, so that the same two laminated resin films were obtained.

The obtained laminated resin films were individually disposed on both sides of an E glass cloth having a thickness of 40 μm so that the resin film C faced the glass woven fabric, and subjected to lamination using a roll laminator while heating at 150° C., and then the PET films on both sides were peeled off, preparing a prepreg having the construction of FIG. 2.

### (Preparation of a Double-Sided Copper-Clad Laminated Plate)

A double-sided copper-clad laminated plate 2 was prepared by conducting substantially the same procedure as in Example 1 except that the prepreg was changed to the above-prepared prepreg.

Using the obtained double-sided copper-clad laminated plate 2, a dimensional change rate was measured in accordance with the method described below. The results are shown in Table 3.

### Comparative Example 1

### (Preparation of a Prepreg)

The two PET film-having resin films B were disposed so that the resin films were in contact with each other, obtaining a laminated material having a construction of “PET film-resin film B-resin film B-PET film”. Then, while heating at 100° C., the laminated material was laminated using a roll laminator to form the two resin films B into a single layer. Then, one PET film was peeled off, preparing a laminated resin film. The same procedure was repeated, so that the same two laminated resin films were obtained.

The obtained laminated resin films were individually disposed on both sides of an E glass cloth having a thickness of 40 μm so that the resin film B faced the glass woven fabric, and subjected to lamination using a roll laminator while heating at 150° C., and then the PET films on both sides were peeled off, preparing a prepreg having the construction of FIG. 5.

### (Preparation of a Double-Sided Copper-Clad Laminated Plate)

A double-sided copper-clad laminated plate 3 was prepared by conducting substantially the same procedure as in Example 1 except that the prepreg was changed to the above-prepared prepreg.

Using the obtained double-sided copper-clad laminated plate 3, a dimensional change rate was measured in accordance with the method described below. The results are shown in Table 3.

### [Evaluation of the Double-Sided Copper-Clad Laminated Plate]

### (Measurement of a Dimensional Change Rate)

With respect to each of the double-sided copper-clad laminated plates obtained in the Examples, the copper foils on both sides were removed by etching to prepare a 5 mm square test specimen. Using a TMA testing machine (Q400, manufactured by TA Instruments), the test specimen was subjected to thermomechanical analysis by a compression method. The test specimen was set in the testing machine along the X-direction, and then subjected to measurement under conditions at a load of 0.4 N and at a temperature increase rate of 45° C./minute using a temperature profile in which the temperature is increased from 25° C. to 260° C. and retained at 260° C. for one hour, and then decreased from 260° C. to 25° C. From a dimensional change of the test specimen after retained at 260° C. for one hour, a dimensional change rate (%) of the test specimen was evaluated. Specifically, a dimensional change rate of the test specimen was determined using the formula shown below. The smaller the dimensional change rate, the more excellent the dimensional stability.

Dimensional change rate (%)=100*(Dimension (mm) immediately after temperature has reached 260° C.−Dimension (mm) after retained at 260° C. for 1 hr)/(Dimension (mm) at 25° C. before start of temperature increase) [Math. 1]

TABLE 3

| | Example | | Comparative Example |
|---|---|---|---|
| | 1 | 2 | 1 |
| Type of copper-clad laminated | 1 | 2 | 3 |
| plate | | | |
| Construction of prepreg | FIG. 1 | FIG. 2 | FIG. 5 |
| Dimensional change rate (%) | 0.044 | 0.048 | 0.058 |

From the results shown in Table 3, it is apparent that the copper-clad laminated plates prepared in Examples 1 and 2 are reduced in the dimensional change rate when retained at a temperature as high as 260° C. for a predetermined time.

In contrast, the copper-clad laminated plate prepared in Comparative Example 1 had a large dimensional change rate when retained at a temperature as high as 260° C. for a predetermined time, as compared to those in Examples 1 and 2.

### REFERENCE SIGNS LIST

100: Prepreg
1: High filled region (high filled layer)
2: Low filled region (low filled layer)

1. A prepreg comprising:
a thermosetting resin composition containing a thermosetting resin (A) and an inorganic filler (B), or a semicured product thereof; and
one fiber substrate,
wherein the prepreg has a high filled region having an inorganic filler (B) content of 45% by volume or more, and a low filled region having an inorganic filler (B) content of less than 45% by volume.

2. The prepreg according to claim 1, wherein the high filled region has an inorganic filler (B) content of 55% by volume or more.

3. The prepreg according to claim 1, wherein the high filled region and the low filled region are in a layer form.

4. The prepreg according to claim 3, which has two layers or more of the high filled region.

5. The prepreg according to claim 1, wherein the thermosetting resin (A) contains at least one member selected from the group consisting of an epoxy resin, a maleimide compound, a phenolic resin, a polyimide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

6. The prepreg according to claim 1, wherein the inorganic filler (B) contains at least one member selected from the group consisting of silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, a molybdic acid compound, talc, aluminum borate, and silicon carbide.

7. A laminated plate comprising: a cured product of the prepreg according to claim 1; and a metal foil.

8. A printed wiring board comprising a cured product of the prepreg according to claim 1.

9. A semiconductor package comprising: the printed wiring board according to claim 8; and a semiconductor element.
